(19) United States
(12) Patent Application Publication
(10) Pub. No.: US 2015/0214443 A1
(43) Pub. Date: Jul. 30, 2015

(54) PHOSPHOR COATING METHOD FOR PRODUCING WAVELENGTH CONVERTING LIGHT-EMITTING DEVICES

(71) Applicant: PHOENIX INTERFACE TECHNOLOGIES LLC, Tempe, AZ (US)

(72) Inventor: Tom Brown, Mesa, AZ (US)

(21) Appl. No.: 14/607,987

(22) Filed: Jan. 28, 2015

Related U.S. Application Data
(60) Provisional application No. 61/932,653, filed on Jan. 28, 2014.

(51) Int. Cl. H01L 33/50; H01L 33/32; H01L 33/34; H01L 33/00

(52) U.S. Cl. CPC H01L 33/502; H01L 33/0054; H01L 33/0075; H01L 33/32; H01L 33/34; H01L 2933/0041

(57) ABSTRACT

The present invention provides a method of producing an optical device or wavelength converting light-emitting device, the method comprising coating a wafer containing at least one material selected from the group of a gallium nitride material and a silicon carbide material with a composite structure comprising an optical material, e.g., wavelength converting material, and a compound represented by formula (I) and curing the composite structure to induce polymerization of said compound. The present invention further provides an optical device, e.g., a wavelength converting light-emitting device produced by this method.

### CROSS-REFERENCE TO RELATED APPLICATIONS

The present application claims the benefit of U.S. Provisional Application No. 61/932,653, filed Jan. 28, 2014, the content of which is incorporated herein in its entirety.

### TECHNICAL FIELD

This application relates to wavelength converting light-emitting devices and methods of making the same. Specifically, the embodiments relate to wafer-level deposition of wavelength converting material.

### BACKGROUND

A light-emitting diode (LED) can provide light in a more efficient manner than an incandescent and/or a fluorescent light source. The relatively high power efficiency associated with LEDs has created an interest in using LEDs to displace conventional light sources in a variety of lighting applications. For example, in some instances LEDs are being used as traffic lights and to illuminate cell phone keypads and displays.

LEDs are solid-state devices that convert electric energy to light, and generally comprise two or more active layers of doped semiconductor materials. When a bias is applied across the doped layers, holes and electrons are injected into the junction where they recombine to generate light. Light is emitted from the junction and from all surfaces of the LED. LEDs generally emit monochromatic light in the blue and ultraviolet (UV) regions of the light spectrum.

Typically, an LED is formed of multiple layers, with at least some of the layers being formed of different materials. In general, the materials and thicknesses selected for the layers influence the wavelength(s) of light emitted by the LED. In addition, the chemical composition of the layers can be selected to promote isolation of injected electrical charge carriers into regions (e.g., quantum wells) for relatively efficient conversion to light. Generally, the layers on one side of the junction where a quantum well is grown are doped with donor atoms that result in high electron concentration (such layers are commonly referred to as n-type layers), and the layers on the opposite side are doped with acceptor atoms that result in a relatively high hole concentration (such layers are commonly referred to as p-type layers).

LEDs also generally include contact structures (also referred to as electrical contact structures or electrodes), which are conductive features of the device that may be electrically connected to a power source. The power source can provide electrical current to the device via the contact structures, e.g., the contact structures can deliver current along the lengths of structures to the surface of the device within which light may be generated.

In addition, LEDs may include a wavelength-converting region (e.g., phosphor region). For example, the wavelength converting material (e.g., phosphor) may be in the form of particles distributed in a second material (e.g., an encapsulant or binder, such as epoxy) to form a composite structure. Wavelength-converting regions can absorb light from a light-generating region (e.g., semiconductor region within an LED) and emit light having a different wavelength. As a result, a light-emitting device incorporating a wavelength-converting region can emit light having wavelength(s) that may not be possible using an LED without such regions.

A problem that occurs during the formation of the composite structure containing the wavelength converting material is the introduction of pockets of air, or bubbles, into the composite structure. These pockets of air impede the efficient transfer of light from the LED through the composite structure. Accordingly, there is a need to develop composite structures and methods for producing them wherein there are few or no air pockets.

In addition, differences in the refractive indices of the binder and the phosphor can cause reflectance that decreases the efficient energy transfer. Composite structures designed to minimize the differences in these refractive indices would also enhance the efficient transmission of light from the LED.

### SUMMARY

The present invention provides a method of producing a wavelength converting light-emitting device, the method comprising coating a wafer containing at least one material selected from the group of a gallium nitride material and a silicon carbide material with a composite structure comprising a wavelength converting material and a compound represented by formula (I):

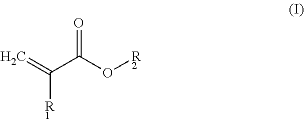

wherein R₁ and R₂ are selected from the group consisting of a hydrogen, an alkyl, a heteroalkyl, a substituted alkyl, and an aryl; and curing the composite structure to induce polymerization of said compound.

In one embodiment, R₁ represents a methyl, an ethyl, a hydroxymethyl, a hydroxyethyl, or a hydrogen; and R₂ represents an alkyl group with 1 to 6 carbon atoms in the compound represented by formula (I). The compound represented by formula (I) may be methyl methacrylate.

In some embodiments, the wavelength converting material is selected from a white emitting phosphor, a yellow emitting phosphor material, a red emitting phosphor material, a green emitting phosphor material, a blue emitting phosphor material, and a quantum dot.

In other aspects of the present disclosure, the composite structure further comprises a metal-containing compound selected from the group consisting of zirconium acrylate, zirconium carboxyethyl acrylate, zirconium bromonorbornanelactone carboxylate triacrylate, zirconium norbornanecarboxylate acrylate, hafnium acrylate, and hafnium carboxyethyl acrylate.

The present disclosure further provides a wavelength converting light-emitting device comprising a wafer containing at least one material selected from the group of a gallium nitride material and a silicon carbide material, wherein the wafer is coated with a composite structure comprising a wavelength converting material and a compound represented by formula (I):

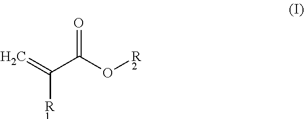

wherein R₁ and R₂ are selected from the group consisting of a hydrogen, an alkyl, a heteroalkyl, a substituted alkyl, and an aryl.

In some embodiments, the wavelength converting material in the composite structure is selected from a white emitting phosphor, a yellow emitting phosphor material, a red emitting phosphor material, a green emitting phosphor material, a blue emitting phosphor material, and a quantum dot.

In other aspects, wherein the composite structure further comprises a metal-containing compound selected from the group consisting of zirconium acrylate, zirconium carboxyethyl acrylate, zirconium bromonorbornanelactone carboxylate triacrylate, zirconium norbornanecarboxylate acrylate, hafnium acrylate, and hafnium carboxyethyl acrylate.

The present disclosure also provides an optical device comprising a substrate, wherein said substrate is coated with a composite structure comprising an optical material and a compound represented by formula (I):

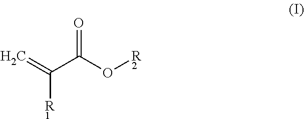

wherein R1 and R2 are selected from the group consisting of a hydrogen, an alkyl, a heteroalkyl, a substituted alkyl, and an aryl.

In one embodiment, R1 represents a methyl, an ethyl, a hydroxymethyl, a hydroxyethyl, or a hydrogen; and R2 represents an alkyl group with 1 to 6 carbon atoms in the compound represented by formula (I). The compound represented by formula (I) may be methyl methacrylate.

In some embodiments of the optical device, the composite structure further comprises a metal-containing compound selected from the group consisting of zirconium acrylate, zirconium carboxyethyl acrylate, zirconium bromonorbornanelactone carboxylate triacrylate, zirconium norbornanecarboxylate acrylate, hafnium acrylate, and hafnium carboxyethyl acrylate.

In other aspects, the composite structure of the optical device may further comprise an initiator selected from the group consisting of an organic peroxide, an azo compound, a metal iodide, and a metal alkyl. In some implementations, the azo compound is is selected from the group consisting of azoisobutylnitrile (AIBN) and 2,2′-Azobis[2-(2-imidazolin-2-yl)propane]. In still other implementation, the organic peroxide is dilauroyl peroxide (LPO).

The present invention additionally provides methods of producing an optical device, the method comprising coating a substrate with a composite structure comprising an optical material and a compound represented by formula (I):

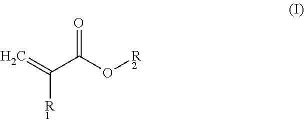

wherein R₁ and R₂ are selected from the group consisting of a hydrogen, an alkyl, a heteroalkyl, a substituted alkyl, and an aryl; and curing the composite structure to induce polymerization of said compound.

In some implementations, the method of producing an optical device further comprises matching the refractive indices of adjacent coatings and/or layers on the substrate, wherein the matching results in adjacent coatings and/or layers with a difference in their refractive indices of less than 0.5.

In one embodiment, R₁ represents a methyl, an ethyl, a hydroxymethyl, a hydroxyethyl, or a hydrogen; and R₂ represents an alkyl group with 1 to 6 carbon atoms in the compound represented by formula (I). The compound represented by formula (I) may be methyl methacrylate.

In other aspects of the method of producing an optical device, the composite structure further comprises a metal-containing compound selected from the group consisting of zirconium acrylate, zirconium carboxyethyl acrylate, zirconium bromonorbornanelactone carboxylate triacrylate, zirconium norbornanecarboxylate acrylate, hafnium acrylate, and hafnium carboxyethyl acrylate.

### BRIEF DESCRIPTION OF THE DRAWINGS

FIG. 1 depicts the three general methods of creating white light with LEDs by 1) using phosphors to convert blue or near-ultraviolet light from the LED into white light, 2) mixing the proper amount of light from red, green, and blue LEDs to yield white light, and 3) using both phosphor-converted LEDs (pcLEDs) and monochromatic LEDs together to produce white light.

FIG. 2A depicts a section of a wavelength converting light-emitting device with a gallium nitride or silicon carbide material, an anti-reflective layer, a composite structure, and a passivation layer. The symbols disbursed throughout the composite structure represent the wavelength converting material present in the binder. FIG. 2B depicts a section of a wavelength converting light-emitting device similar to FIG. 2A, except that the composite structure is combined with the anti-reflective layer.

### DETAILED DESCRIPTION

As used herein, the verb “comprise” as is used in this description and in the claims and its conjugations are used in its non-limiting sense to mean that items following the word are included, but items not specifically mentioned are not excluded. In addition, reference to an element by the indefinite article “a” or “an” does not exclude the possibility that more than one of the elements are present, unless the context clearly requires that there is one and only one of the elements. The indefinite article “a” or “an” thus usually means “at least one”.

As used herein, a “gallium nitride material” includes gallium nitride (GaN) and its alloys such as aluminum gallium nitride (AlGaN), indium gallium nitride (InGaN), and aluminum indium gallium nitride (AlInGaN). These materials are semiconductor compounds that have a relatively wide, direct bandgap which permits highly energetic electronic transitions to occur. Such electronic transitions can result in gallium nitride materials having a number of attractive properties including the ability to efficiently emit blue light, the ability to transmit signals at high frequency, and others.

As used herein, a “silicon carbide material” includes silicon carbide in any of its crystalline forms. The term encompasses the various polymorphs of silicon carbide, such as alpha silicon carbide (α-SiC) and beta silicon carbide (β-SiC) and all polytypes (e.g., 3C, 4H, and 6H).

A “wavelength converting material” is a material that converts monochromatic light emitted from an LED to another wavelength.

As used herein, the term “alkyl” refers to hydrocarbon containing normal, secondary, tertiary or cyclic carbon atoms. For example, an alkyl group can have 1 to 20 carbon atoms (i.e., C₁-C₂₀ alkyl), 1 to 10 carbon atoms (i.e., C₁-C₁₀ alkyl), or 1 to 6 carbon atoms (i.e., C₁-C₆ alkyl). Examples of suitable alkyl groups include, but are not limited to, methyl (Me, —CH₃), ethyl (Et, —CH₂CH₃), 1-propyl (n-Pr, n-propyl, —CH₂CH₂CH₃), 2-propyl (i-Pr, i-propyl, —CH(CH₃)₂), 1-butyl (n-Bu, n-butyl, —CH₂CH₂CH₂CH₃), 2-methyl-1-propyl (i-Bu, i-butyl, —CH₂CH(CH₃)₂), 2-butyl (s-Bu, s-butyl, —CH(CH₃)CH₂CH₃), 2-methyl-2-propyl (t-Bu, t-butyl, —C(CH₃)₃), 1-pentyl (n-pentyl, —CH₂CH₂CH₂CH₂CH₃), 2-pentyl (—CH(CH₃)CH₂CH₂CH₃), 3-pentyl (—CH(CH₂CH₃)₂), 2-methyl-2-butyl (—C(CH₃)₂CH₂CH₃), 3-methyl-2-butyl (—CH(CH₃)CH(CH₃)₂), 3-methyl-1-butyl (—CH₂CH₂CH(CH₃)₂), 2-methyl-1-butyl (—CH₂CH(CH₃)CH₂CH₃), 1-hexyl (—CH₂CH₂CH₂CH₂CH₂CH₃), 2-hexyl (—CH(CH₃)CH₂CH₂CH₂CH₃), 3-hexyl (—CH(CH₂CH₃)(CH₂CH₂CH₃)), 2-methyl-2-pentyl (—C(CH₃)₂CH₂CH₂CH₃), 3-methyl-2-pentyl (—CH(CH₃)CH(CH₃)CH₂CH₃), 4-methyl-2-pentyl (—CH(CH₃)CH₂CH(CH₃)₂), 3-methyl-3-pentyl (—C(CH₃)(CH₂CH₃)₂), 2-methyl-3-pentyl (—CH(CH₂CH₃)CH(CH₃)₂), 2,3-dimethyl-2-butyl (—C(CH₃)₂CH(CH₃)₂), 3,3-dimethyl-2-butyl (—CH(CH₃)C(CH₃)₃, octyl (—(CH₂)₇CH₃), and isomers thereof.

As used herein, the term “aryl” refers to an aromatic hydrocarbon radical derived by the removal of one hydrogen atom from a single carbon atom of a parent aromatic ring system. For example, an aryl group can have 1 to 20 carbon atoms, 1 to 4 carbon atoms, 4 to 20 carbon atoms, 4 to 18 carbon atoms, 4 to 16 carbon atoms, 4 to 14 carbon atoms, 4 to 12 carbon atoms, 4 to 10 carbon atoms, 4 to 8 carbon atoms, or 4 to 6 carbon atoms. Typical aryl groups include, but are not limited to, radicals derived from benzene (e.g., phenyl), substituted benzene, naphthalene, anthracene, biphenyl, and the like.

As used herein, the term “substituted alkyl” means alkyl in which one or more hydrogen atoms are each independently replaced with a non-hydrogen substituent.

As used herein, the term “heteroalkyl” refers to an alkyl group where one or more carbon atoms have been replaced with a heteroatom, such as, O, N, or S. For example, if the carbon atom of the alkyl group, which is attached to the parent molecule, is replaced with a heteroatom (e.g., O, N, or S) the resulting heteroalkyl groups are, respectively, an alkoxy group (e.g., —OCH₃, etc.), an amine (e.g., —NHCH₃, —N(CH₃)₂, etc.), or a thioalkyl group (e.g., —SCH₃). A heteroalkyl group can have, for example, 1 to 20 carbon atoms, 1 to 4 carbon atoms, 4 to 20 carbon atoms, 4 to 18 carbon atoms, 4 to 16 carbon atoms, 4 to 14 carbon atoms, 4 to 12 carbon atoms, 4 to 10 carbon atoms, 4 to 8 carbon atoms, or 4 to 6 carbon atoms. A C₁-C₆ heteroalkyl group means a heteroalkyl group having 1 to 6 carbon atoms.

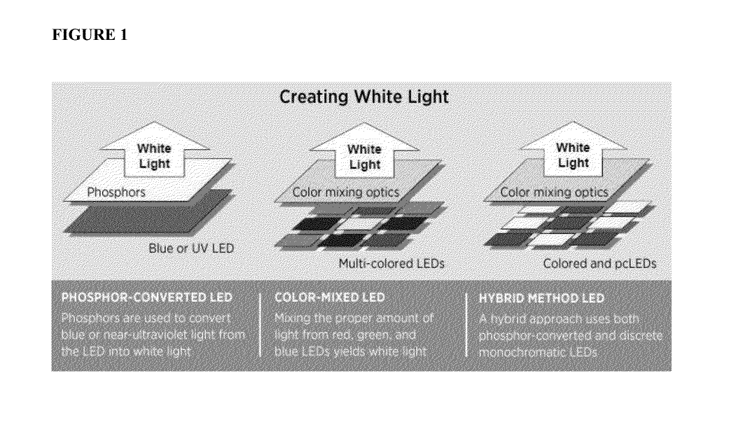

Current wavelength converting material (e.g., phosphor) deposition processes include the use of organic solvents that produce pockets of air or bubbles in the composite structure. The methods of the present disclosure significantly decrease the incidence of these air pockets thus enhancing the transmission of the light produced by the wavelength converting light-emitting device. These methods may be used to improve the efficiency of wavelength converting light-emitting devices that utilize phosphor-converted LEDs alone or in combination with discrete monochromatic LEDs (see the methods of creating white light labelled “Phosphor-Converted LED” and “Hybrid Method LED” in FIG. 1).

In optics the refractive index or index of refraction n of a substance (optical medium) is a dimensionless number that describes how light, or any other radiation, propagates through that medium. It is defined as

$$n = \frac{c}{v} ,$$

where c is the speed of light in vacuum and v is the speed of light in the substance. For example, the refractive index of water is 1.33, meaning that light travels 1.33 times as fast in vacuum as it does in water.

Reflectivity and reflectance generally refer to the fraction of incident electromagnetic power that is reflected at an interface. The reflectance (or reflectivity) is always a positive real number. The reflection angle is equal to the incidence angle, and the amount of light that is reflected is determined by the reflectivity of the surface. The reflectivity can be calculated from the refractive index and the incidence angle with the Fresnel equations, which for normal incidence reduces to

$$R = {\vert \frac{{n}_{1} - {n}_{2}}{{n}_{1} + {n}_{2}} \vert}^{2} .$$

According to the CIE (the International Commission on Illumination), reflectivity is distinguished from reflectance by the fact that reflectivity is a value that applies to thick reflecting objects. When reflection occurs from thin layers of material, internal reflection effects can cause the reflectance to vary with surface thickness. Reflectivity is the limit value of reflectance as the sample becomes thick; it is the intrinsic reflectance of the surface, hence irrespective of other parameters such as the reflectance of the rear surface. Another way to interpret this is that the reflectance is the fraction of electromagnetic power reflected from a specific sample, while reflectivity is a property of the material itself.

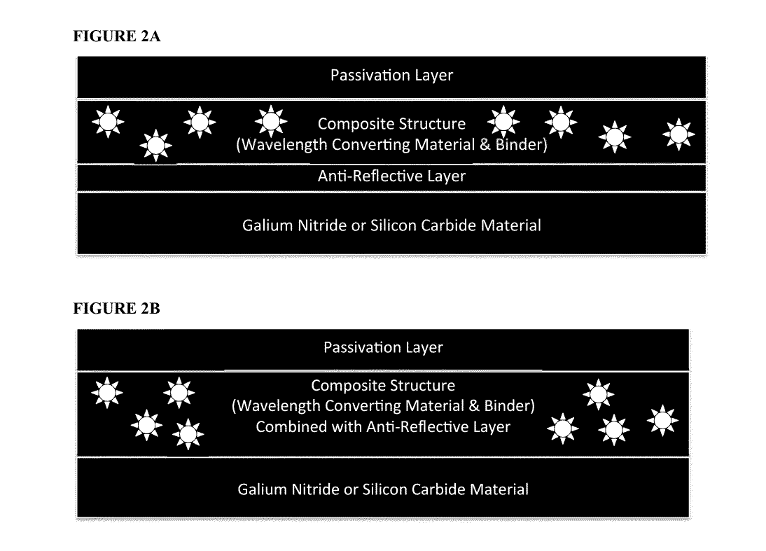

FIGS. 2A and 2B present cross-sections of embodiments of the disclosed wavelength converting light-emitting device. In FIG. 2A, the cross-section has an antireflective layer adjacent to a gallium nitride or silicon carbide material followed by a composite structure and a passivation layer. The composite structure contains the wavelength converting material and the binder. In FIG. 2B, the composite structure and the anti-reflective layers are combined. As light passes from the gallium nitride or silicon carbide material through the adjacent layers of the device, the difference between the refractive index of one material and that of the adjacent material should be minimized to reduce reflectance and increase the amount of transmitted light. An object of the present invention is to prevent the introduction of air, which has a refractive index of about 1.0, into the composite structure.

In some embodiments, the present disclosure provides a gallium nitride or silicon carbide material, an anti-reflective layer, a composite structure, and a passivation layer as shown in FIG. 2A or FIG. 2B. The refractive indices of each of these layers may be 1.3 to 3.0; e.g., any range within 1.3 to 3.0, such as 1.3 to 2.0, 1.5 to 2.5, 1.8 to 3.0, etc. The refractive indices of each of these layers may be about 1.3, about 1.4, about 1.5, about 1.6, about 1.7, about 1.8, about 1.9, about 2.0, about 2.1, about 2.2, about 2.3, about 2.4, about 2.5, about 2.6, about 2.7, about 2.8, about 2.9, or about 3.0. In one embodiment, the refractive index of the gallium nitride or silicon carbide material is about 2.5, the refractive index of the anti-reflective layer is about 2.1, the refractive index of the composite structure is about 1.8, and the refractive index of the passivation layer is about 1.5.

The gallium nitride material or silicon carbide material may be in the form of a wafer or a light emitting diode (LED) chip. In some embodiments, silicon carbide (SiC) is combined with the gallium nitride material. SiC may be used as a substrate for growing gallium nitride (GaN) devices, and it also serves as a heat spreader in high-power LEDs.

In some aspects, the present disclosure provides methods of producing a wavelength converting light-emitting device comprising coating a wafer containing at least one material selected from the group of a gallium nitride material and a silicon carbide material with a composite structure comprising a wavelength converting material and a compound represented by formula (I):

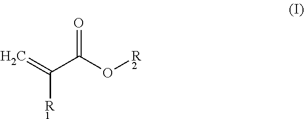

wherein R₁ and R₂ are selected from the group consisting of a hydrogen, an alkyl, a heteroalkyl, a substituted alkyl, and an aryl; and curing the composite structure to induce polymerization of said compound. In some embodiments, the compound represented by formula (I) is methyl methacrylate.

In other aspects, the present disclosure provides methods of producing an optical device comprising coating a substrate with a composite structure comprising an optical material and a compound represented by formula (I):

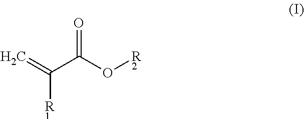

wherein R₁ and R₂ are selected from the group consisting of a hydrogen, an alkyl, a heteroalkyl, a substituted alkyl, and an aryl; and curing the composite structure to induce polymerization of said compound. In some embodiments, the optical material may be a wavelength converting material. In some embodiments, the compound represented by formula (I) is methyl methacrylate.

In certain embodiments, the methods of the present disclosure further comprises matching the refractive indices of adjacent coatings and/or layers on the wafer or the substrate, wherein the matching results in adjacent coatings and/or layers with a difference in their refractive indices of less than 0.1, of less than 0.2, of less than 0.3, of less than 0.4, of less than 0.5, of less than 0.6, of less than 0.7, of less than 0.8, of less than 0.9, or of less than 1.0.

Curing of the composite structure can result from exposure to thermal energy or irradiation with ultraviolet (UV) or visible light. When thermal energy is used, the initiator is heated until a bond is homolytically cleaved, producing two radicals as shown below for the thermal decomposition of dicumyl peroxide. This method is used most often with organic peroxides or azo compounds.

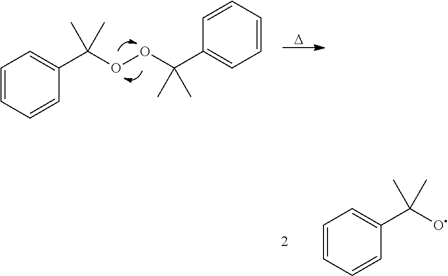

With irradiation using ultraviolet (UV) or visible light, the radiation cleaves a bond homolytically, producing two radicals as shown below with the initiator, AIBN. This method is used most often with metal iodides, metal alkyls, and azo compounds.

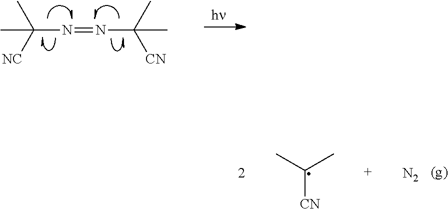

Specific initiators that may be used for curing of the composite structure include, for example, azoisobutylnitrile (AIBN), dilauroyl peroxide (LPO), and 2,2′-Azobis[2-(2-imidazolin-2-yl)propane].

In some embodiments, the curing of the composite structure occurs in a chamber with a relative humidity of about 1%, about 2%, about 3%, about 4%, about 5%, about 6%, about 7%, about 8%, about 9%, about 10%, about 15%, about 20%, about 25%, about 30%, about 35%, or about 40%. In some embodiments, the curing of the composite structure occurs in a chamber with a relative humidity of less than 40%, less than 35%, less than 30%, less than 25%, less than 20%, less than 15%, less than 10%, or less than 5%. The presence of a small volume of water in the composite structure during the curing process influences the formation of the polymer and the incorporation of the optical material, for example a wavelength converting material, into the polymer. Without wishing to be bound to any theory, the water may take part in the hydrolysis of some of the bonds between the polymer and wavelength converting material and/or the metal-containing compounds thereby producing greater dispersion of the particulates and changing the refractive index of the cured composite structure. When curing with thermal energy, the presence of water may also reduce the temperature and the amount of time required to complete the curing process.

In other aspects of the present disclosure, the composite structure further comprises an organic solvent prior to curing. The organic solvent may increase the solubility of the compound represented by formula (I). Examples of organic solvents that may be used include n-butanol, isobutanol, 2-butanol, tert-butanol, 2-butanone, toluene, chloroform, ethanol, diethyl ether, diethylene glycol, dimethyl sulfoxide (DMSO), ethyl acetate, methyl t-butyl ether (MTBE), N-methyl-2-pyrrolidinone (NMP), and nitromethane.

In certain aspects, the method of the present disclosure includes applying a vacuum to one or more of the layers of the wavelength converting light-emitting device or of the optical device. The vacuum may further reduce the incidence of air pockets or bubbles in the one or more layers.

In some embodiments presented herein, methods are provided for depositing a composite structure containing a wavelength converting material (e.g., phosphors) onto light-emitting (e.g., LED) devices. For example, the composite structure, or wavelength converting material layer, can be deposited on the emission surface of the light-emitting devices. In some cases, the wavelength converting material layer is deposited on a wafer that is subsequently processed to form multiple light-emitting devices.

The composite structure, or wavelength-converting layer, is a region that can include one or more wavelength-converting materials that can convert the wavelength of absorbed light. The wavelength-converting materials can function by absorbing light having a first wavelength and emitting light having a second wavelength (e.g., longer wavelengths).

In some aspects of the present disclosure, light from a blue emitting LED may be converted to white light by surrounding the LED with a wavelength converting material such as a yellow phosphor, polymer or dye, with a typical phosphor being cerium-doped yttrium aluminum garnet (Ce:YAG). [See Nichia Corp. white LED, Part No. NSPW300BS, NSPW312BS, etc.; Cree® Inc. EZBright™ LEDs, XThin™ LEDs, etc.; See also U.S. Pat. No. 5,959,316 to Lowrey, “Multiple Encapsulation of Phosphor-LED Devices”]. The surrounding phosphor material “downconverts” the wavelength of some of the LED's blue light, changing its color to yellow. Some of the blue light passes through the phosphor without being changed while a substantial portion of the light is downconverted to yellow. The LED emits both blue and yellow light, which combine to provide a white light. In another approach light from a violet or ultraviolet emitting LED may be converted to white light by surrounding the LED with multicolor phosphors or dyes.

Certain metal-containing compounds may be included in the composite structure to maintain a relatively high refractive index (e.g. greater than 1.5). These metal-containing compounds include zirconium acrylate, zirconium carboxyethyl acrylate, zirconium bromonorbornanelactone carboxylate triacrylate, zirconium norbornanecarboxylate acrylate, hafnium acrylate, and hafnium carboxyethyl acrylate. Similar metal-containing compounds such as multifunctional metal-containing acrylates with germanium, titanium, and niobium may also be used. Additional metal-containing compounds are described in U.S. Pat. No. 7,888,441 and U.S. Pat. No. 7,629,424, which are hereby incorporated by reference in their entirety.

In some embodiments, the wavelength converting material may be a single phosphor or a combination of phosphors. The phosphor material can be present in particulate form. The particles may be distributed in a second material (e.g., an encapsulant or binder, such as epoxy or a polymer comprising a compound represented by Formula I) to form a composite structure.

For example, the wavelength converting material can comprise yttrium aluminum garnet (YAG, with chemical formula Y₃Al₅O₁₂). YAG single crystalline phosphors are commercially available from VLOC Subsidiary of II-IV Incorporated. The YAG host is a stable compound that is mechanically robust, physically hard and optically isotropic.

The YAG host can be combined with other compounds to achieve the desired emission wavelength. In one embodiment where the single crystalline phosphor absorbs blue light and re-emits yellow, the single crystalline phosphors can comprise YAG:Ce. This embodiment is particularly applicable to LEDs that emit a white light combination of blue and yellow light. A full range of broad yellow spectral emission is possible using conversion particles made of phosphors based on the (Gd,Y)₃(Al,Ga)₅O₁₂:Ce system, which include Y₃Al₅O₁₂:Ce (YAG). Other yellow phosphors that can be used for white emitting LED chips include:
Tb₃₋ₓREₓO₁₂:Ce (TAG); RE=Y, Gd, La, Lu; or
Sr_{2-x-y}BaₓCa_{y}SiO₄:Eu.

In other embodiments, other compounds can be used with YAG host for absorption and re-emission of different wavelengths of light. For example, a YAG:Nb single crystal phosphors can be provided to absorb blue light and re-emit red light. First and second phosphors can also be combined for higher CRI white of different white hue (warm white) with the yellow phosphors above combined with red phosphors. Different red phosphors can be used including:
SrₓCa₁₋ₓS:Eu, Y; Y=halide;
CaSiAlN₃:Eu; or
Sr_{2-y}Ca_{y}SiO₄:Eu.

Other phosphors can be used to create saturated color emission by converting substantially all light to a particular color. For example, the following phosphors can be used to generate green saturated light:
SrGa₂S₄:Eu;
Sr_{2-y}Ba_{y}SiO₄:Eu; or
SrSi₂O₂N₂:Eu.

The following lists some additional suitable phosphors that can be used as conversion particles, although others can be used. Each exhibits excitation in the blue and/or UV emission spectrum, provides a desirable peak emission, has efficient light conversion, and has acceptable Stokes shift:

### Yellow/Green

(Sr, Ca, Ba) (Al, Ga)₂S₄:Eu²⁺
Ba₂(Mg, Zn) Si₂O₇:Eu²+
Gd_{0.46}Sr_{0.31}Al_{1.23}OₓF_{1.38}:Eu_{0.05}²⁺
(Ba_{1-x-y}SrₓCa_{y})SiO₄:Eu
Ba₂SiO₄:Eu²⁺

### Red

Lu₂O₃:Eu³⁺
(Sr₂₋ₓLaₓ) (Ce₁₋ₓEuₓ)O₄
Sr₂Ce₁₋ₓEuₓO₄
Sr₂₋ₓEuₓCeO₄
SrTiO₃:Pr³⁺,Ga³⁺
CaAlSiN₃:Eu²⁺
Sr₂Si₅N₈:EU²⁺

Any suitable phosphor material may be used. In some embodiments, the phosphor material may be a yellow phosphor material (e.g., (Y,Gd)(Al,Ga)G:Ce3+, sometimes referred to as a “YAG” (yttrium, aluminum, garnet) phosphor), a red phosphor material (e.g., L2O2S:Eu3+), a green phosphor material (e.g., ZnS:Cu,Al,Mn), a blue phosphor material (e.g., (Sr,Ca,Ba,Mg)10(PO4)6Cl:Eu2±), and/or a white phosphor material. Other phosphor materials are also possible. Suitable phosphor materials have been described, for example, in U.S. Pat. No. 7,196,354, filed Sep. 29, 2005, entitled “Wavelength-converting Light-emitting Devices,” by Erchak, et al., which is incorporated herein by reference in its entirety. As described further below, in some embodiments, wavelength converting material particles are mixed with Spin-on-glass (SOG) material and subsequently spun onto LED wafer. In some embodiments, S-O-G (Futurrex, IC1-200) can be used as the binding material for wavelength converting material, such as phosphor. In some embodiments, no silicone material is present in this process. In some embodiments, wavelength converting material particles are mixed with silicone material and subsequently spun onto LED wafer. In some embodiments, wavelength converting material particles are mixed with epoxy material and subsequently spun onto LED wafer. In addition to spin coating, the wavelength converting material (and any additional elements such as silicone material, epoxy, S-O-G, etc.) may be deposited via spray-coating, ink-jet printing, screen printing, among other methods. In some embodiments, a mixture of wavelength converting material powder (e.g., YAG:Ce powder with average particle size 1-10 um, which can be obtained from Phosphor Technology Corp.) and S-O-G (e.g., in a ratio of 1 g:1.5 ml, in a ratio of 0.5-0.7 g:1 ml) can be applied to wafers.

In some embodiments, the wavelength material is a quantum dot. A quantum dot is a nano crystal of a semiconductor material having a diameter ranging from about 1 nm to 10 nm, exhibiting a quantum confinement effect. The quantum dots may convert the wavelength of light emitted from the light-emitting device to generate wavelength-converted light, namely, fluorescence. The quantum dot may be, for example, an Si-based nano crystal, a group II-IV compound semiconductor nano crystal, a group III-V compound semiconductor nano crystal, a group IV-VI compound semiconductor nano crystal, or the like. In some embodiments, these nano crystals may be used alone as the quantum dot or a mixture thereof may be used.

Referring to the quantum dot material, the group II-VI-based compound semiconductor nano crystal may be, for example, any one selected from the group consisting of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HggZnTe, CdZnSeS, CdZnSeTe, CdZnSTe, CdHgSeS, CdHgSeTe, CdHgSTe, HgZnSeS, HgZnSeTe, and HgZnSTe. The group III-V-based compound semiconductor nano crystal may be, for example, any one selected from the group consisting of GaN, GaP, GaAs, AlN, Alp, AlAs, InN, InP, InAs, GaNP, GaNAs, GaPAs, AlNP, AINAs, AlPAs, InNP, InNAs, InPAs, GaAlNP, GaAlNAs, GaAlPAs, GaInNP, GaInNAs, GalnPAs, InAlNP, InAlNAs, and InAlPAs. The group IV-VI-based compound semiconductor nano crystal may be, for example, SbTe.

In some embodiments, the average particle size of the wavelength converting material may be less than 100 microns. In some embodiments, the average particle size is less than 30 microns. In some embodiments, the average particle size of the wavelength converting material powder may be between about 1 and 10 microns, between about 4 and 16 microns, between about 10 and 30 microns, or between about 30 and 100 microns. It should be understood that other particle sizes are also possible than the ranges described herein.

In addition, the ratio of wavelength converting material to binder (e.g., compound represented by formula I) may vary. For example, the ratio of wavelength converting material to binder may be at least about 0.1 g/mL, at least 0.5 g/mL, at least 1 g/mL, at least 2 g/mL, or higher. Good uniformity and thickness can be obtained, as with well known spin-coating processes for other materials. Dense films may be obtained as shown by SEM images showing that the wavelength converting material particles are densely packed. Pre-baked S-O-G can serve as a strong binding material. In some embodiments, wafers can undergo quick dump rinsing, spin rinse drying, and/or laser dicing without noticeable wavelength converting material loss. In some embodiments, bond pad(s) can be protected during wavelength converting material layer application (e.g., phosphor layer application) by a mask layer over the bond pad(s). The mask layer can be formed using photo-lithography. In some embodiments, mask layer lift-off may be performed to remove the mask layer and any wavelength converting material layer over the mask layer (e.g., using acetone, soaking for 10-30 minutes with gentle agitation).

The contents of all references, patents, and published patent applications cited throughout this application, as well as the Figures, are incorporated herein by reference in their entirety for all purposes.

Unless defined otherwise, all technical and scientific terms herein have the same meaning as commonly understood by one of ordinary skill in the art to which this invention belongs. Although any methods and materials, similar or equivalent to those described herein, can be used in the practice or testing of the present invention, the preferred methods and materials are described herein. All publications, patents, and patent publications cited are incorporated by reference herein in their entirety for all purposes.

The publications discussed herein are provided solely for their disclosure prior to the filing date of the present application. Nothing herein is to be construed as an admission that the present invention is not entitled to antedate such publication by virtue of prior invention.

While the invention has been described in connection with specific embodiments thereof, it will be understood that it is capable of further modifications and this application is intended to cover any variations, uses, or adaptations of the invention following, in general, the principles of the invention and including such departures from the present disclosure as come within known or customary practice within the art to which the invention pertains and as may be applied to the essential features hereinbefore set forth and as follows in the scope of the appended claims.

What is claimed is:

1. A method of producing a wavelength converting light-emitting device, the method comprising:
coating a wafer containing at least one material selected from the group of a gallium nitride material and a silicon carbide material with a composite structure comprising a wavelength converting material and a compound represented by formula (I): 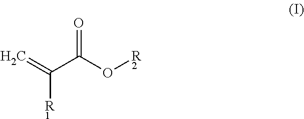
wherein R₁ and R₂ are selected from the group consisting of a hydrogen, an alkyl, a heteroalkyl, a substituted alkyl, and an aryl; and
curing the composite structure to induce polymerization of said compound.

2. The method of claim 1, further comprising matching the refractive indices of adjacent coatings and/or layers on the wafer, wherein the matching results in adjacent coatings and/or layers with a difference in their refractive indices of less than 0.5.

3. The method of claim 1, wherein in said compound R₁ represents a methyl, an ethyl, a hydroxymethyl, a hydroxyethyl, or a hydrogen; and R₂ represents an alkyl group with 1 to 6 carbon atoms.

4. The method of claim 3, wherein said compound is methyl methacrylate.

5. The method of claim 1, wherein the wavelength converting material is selected from a white emitting phosphor, a yellow emitting phosphor material, a red emitting phosphor material, a green emitting phosphor material, a blue emitting phosphor material, and a quantum dot.

6. The method of claim 1, wherein the composite structure further comprises a metal-containing compound selected from the group consisting of zirconium acrylate, zirconium carboxyethyl acrylate, zirconium bromonorbornanelactone carboxylate triacrylate, zirconium norbornanecarboxylate acrylate, hafnium acrylate, and hafnium carboxyethyl acrylate.

7. The method of claim 1, wherein curing the composite structure results from exposure to thermal energy or irradiation with ultraviolet (UV) or visible light.

8. The method of claim 1, wherein the composite structure further comprises an initiator selected from the group consisting of organic peroxides, azo compounds, metal iodides, and metal alkyls.

9. The method of claim 8, wherein the azo compound is selected from the group consisting of azoisobutylnitrile (AIBN) and 2,2′-Azobis[2-(2-imidazolin-2-yl)propane].

10. The method of claim 8, wherein the organic peroxide is dilauroyl peroxide (LPO).

11. The method of claim 1, wherein curing the composite structure occurs in a chamber with a relative humidity of about 10%.

12. A wavelength converting light-emitting device comprising a wafer containing at least one material selected from the group of a gallium nitride material and a silicon carbide material, wherein said wafer is coated with a composite structure comprising a wavelength converting material and a compound represented by formula (I): 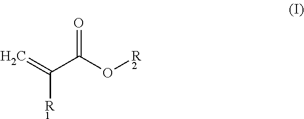
wherein R₁ and R₂ are selected from the group consisting of a hydrogen, an alkyl, a heteroalkyl, a substituted alkyl, and an aryl.

13. The wavelength converting light-emitting device of claim 12, wherein in said compound R₁ represents a methyl, an ethyl, a hydroxymethyl, a hydroxyethyl, or a hydrogen; and R₂ represents an alkyl group with 1 to 6 carbon atoms.

14. The wavelength converting light-emitting device of claim 13, wherein said compound is methyl methacrylate.

15. The wavelength converting light-emitting device of claim 12, wherein the wavelength converting material is selected from a white emitting phosphor, a yellow emitting phosphor material, a red emitting phosphor material, a green emitting phosphor material, a blue emitting phosphor material, and a quantum dot.

16. The wavelength converting light-emitting device of claim 12, wherein the composite structure further comprises a metal-containing compound selected from the group consisting of zirconium acrylate, zirconium carboxyethyl acrylate, zirconium bromonorbornanelactone carboxylate triacrylate, zirconium norbornanecarboxylate acrylate, hafnium acrylate, and hafnium carboxyethyl acrylate.

17. The wavelength converting light-emitting device of claim 12, wherein the composite structure further comprises an initiator selected from the group consisting of organic peroxides, azo compounds, metal iodides, and metal alkyls.

18. The wavelength converting light-emitting device of claim 17, wherein the azo compound is selected from the group consisting of azoisobutylnitrile (AIBN) and 2,2′-Azobis[2-(2-imidazolin-2-yl)propane].

19. The wavelength converting light-emitting device of claim 17, wherein the organic peroxide is dilauroyl peroxide (LPO).

20. An optical device comprising a substrate, wherein said substrate is coated with a composite structure comprising an optical material and a compound represented by formula (I): 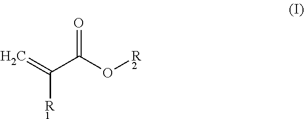
wherein R1 and R2 are selected from the group consisting of a hydrogen, an alkyl, a heteroalkyl, a substituted alkyl, and an aryl.
